(19) United States
(12) Patent Application Publication
(10) Pub. No.: US 2007/0224740 A1
(43) Pub. Date: Sep. 27, 2007

(54) THIN-FILM TRANSISTOR AND METHOD OF FABRICATING THE SAME

(76) Inventors: Kaichi FUKUDA, Fukaya-shi (JP); Satoru Murakami, Kumagaya-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/681,949

(22) Filed: Mar. 5, 2007

(30) Foreign Application Priority Data
Mar. 23, 2006 (JP) 2006-081047

(51) Int. Cl. H01L 21/84

(52) U.S. Cl. 438/149

(57) ABSTRACT

A conductive film is processed in a first etching step, and thinned by reprocessing using light ashing. An exposed portion of an insulating film is etched away in the film thickness direction, thereby forming a step on the insulating film. Impurity ions are implanted into a semiconductor layer.

### CROSS-REFERENCE TO RELATED APPLICATIONS

This application is based upon and claims the benefit of priority from prior Japanese Patent Application No. 2006-081047, filed Mar. 23, 2006, the entire contents of which are incorporated herein by reference.

### BACKGROUND OF THE INVENTION

1. Field of the Invention

The present invention relates to a thin-film transistor formed on a glass substrate, and a method of fabricating the same.

2. Description of the Related Art

The fabrication of an n-channel C-MOS thin-film transistor generally requires photolithography twice in order to form an LDD and n⁺-type region.

As disclosed in, e.g., Jpn. Pat. Appln. KOKAI Publication No. 11-163366, therefore, a method which requires photolithography only once by forming an LDD of an n-channel thin-film transistor in self-alignment is proposed. However, if a gate electrode is etched for the second time after a first implantation step, a resist often peels off to cause disconnection before the second etching. Also, the resist hardened in the first implantation step does not taper the gate electrode. This often poses the problem of yield, such as an interlayer short circuit or disconnection, or the problem of reliability, such as the penetration of contaminants from the outside.

### BRIEF SUMMARY OF THE INVENTION

The present invention has been made in consideration of the above situation, and has as its object to provide a thin-film transistor which prevents, e.g., an interlayer short circuit, disconnection, and the penetration of contaminants from the outside, and a method of fabricating the same.

A thin-film transistor fabrication method of the present invention comprises a step of forming an island-like semiconductor layer on an insulating substrate, a step of forming an insulating film to cover the semiconductor layer, a step of forming a conductive film to cover the insulating film, a first etching step of forming a pattern of a photoresist on the conductive film, and processing the conductive film by using the photoresist as a mask, a step of thinning the pattern of the photoresist by reprocessing, a second etching step of thinning the conductive film by reprocessing by using the reprocessed pattern of the photoresist as a mask, and forming a step on the insulating film by etching away, in a film thickness direction, a portion of the insulating film which is exposed in the first etching step for the conductive film, an ion implantation step of implanting impurity ions into the semiconductor layer by using the photoresist and conductive film that have undergone the second etching step as masks, and a step of removing the photoresist.

The present invention can provide a high-quality, thin-film transistor without causing any of, e.g., an interlayer short circuit, disconnection, and the penetration of contaminants from the outside.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the generation description given above and the detailed description of the embodiments given below, serve to explain the principles of the invention.

FIG. 1 is a schematic view showing the sectional structure of an example of a thin-film transistor substrate according to the present invention;

FIG. 2 is a schematic view showing a part of FIG. 1;

FIG. 3 is a view for explaining the first example of a thin-film transistor substrate fabrication method according to the present invention;

FIG. 4 is a view for explaining the first example of the thin-film transistor substrate fabrication method according to the present invention;

FIG. 5 is a view for explaining the first example of the thin-film transistor substrate fabrication method according to the present invention;

FIG. 6 is a view for explaining the first example of the thin-film transistor substrate fabrication method according to the present invention;

FIG. 7 is a view for explaining the first example of the thin-film transistor substrate fabrication method according to the present invention;

FIG. 8 is a view for explaining the first example of the thin-film transistor substrate fabrication method according to the present invention;

FIG. 9 is a view for explaining the first example of the thin-film transistor substrate fabrication method according to the present invention;

FIG. 10 is a view for explaining the first example of the thin-film transistor substrate fabrication method according to the present invention;

FIG. 11 is a view for explaining the first example of the thin-film transistor substrate fabrication method according to the present invention;

FIG. 12 is a view for explaining the first example of the thin-film transistor substrate fabrication method according to the present invention;

FIG. 13 is a view for explaining the first example of the thin-film transistor substrate fabrication method according to the present invention;

FIG. 14 is a view for explaining the first example of the thin-film transistor substrate fabrication method according to the present invention;

FIG. 15 is a view for explaining the second example of the thin-film transistor substrate fabrication method according to the present invention;

FIG. 16 is a view for explaining the second example of the thin-film transistor substrate fabrication method according to the present invention;

FIG. 17 is a view for explaining the second example of the thin-film transistor substrate fabrication method according to the present invention;

FIG. 18 is a view for explaining the second example of the thin-film transistor substrate fabrication method according to the present invention;

FIG. 19 is a view for explaining the second example of the thin-film transistor substrate fabrication method according to the present invention;

FIG. 20 is a view for explaining an example of the fabrication of a gate electrode and gate interconnection preferably used in the present invention;

FIG. 21 is a view for explaining the example of the fabrication of the gate electrode and gate interconnection preferably used in the present invention;

FIG. 22 is a view for explaining the example of the fabrication of the gate electrode and gate interconnection preferably used in the present invention; and

FIG. 23 is a view for explaining the example of the fabrication of the gate electrode and gate interconnection preferably used in the present invention.

### DETAILED DESCRIPTION OF THE INVENTION

The present invention will be described in more detail below with reference to the accompanying drawing.

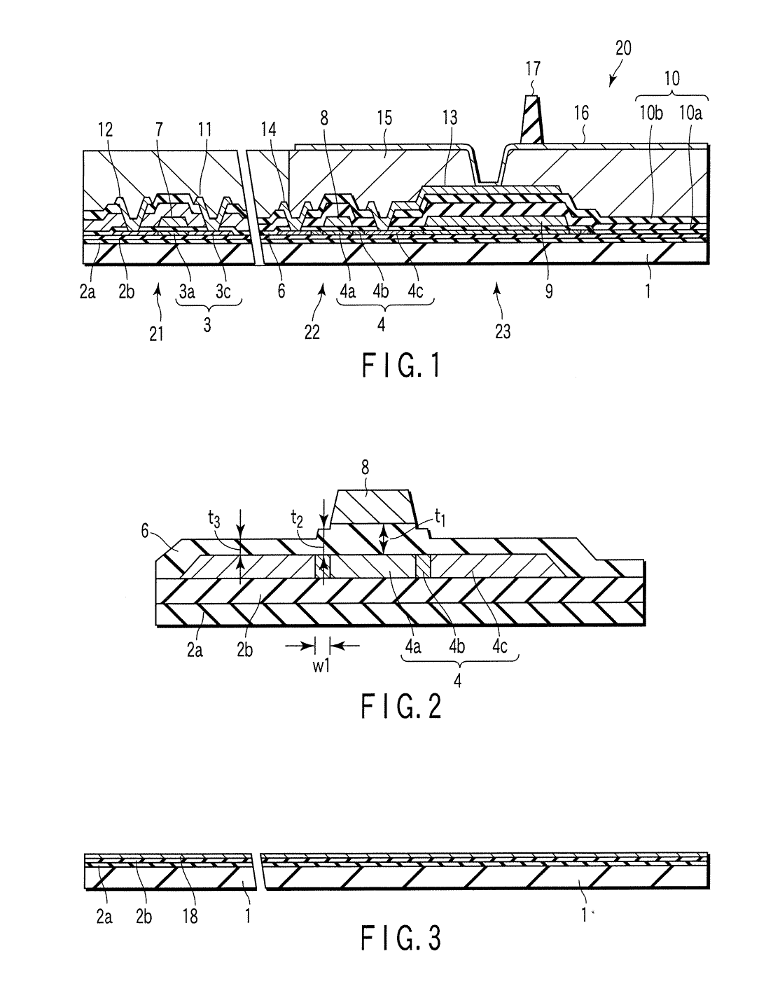

FIG. 1 is a schematic view showing the sectional structure of an example of a thin-film transistor substrate according to the present invention.

The thin-film transistor substrate of this example can be used as a thin-film transistor array substrate for use in a top gate type semi-transmitting, liquid-crystal display device. Although the thin-film transistor array substrate for use in a semi-transmitting, liquid-crystal display device will be taken as an example, the present invention is of course also applicable to an organic EL display device and the like.

As shown in FIG. 1, a thin-film transistor substrate 20 comprises a transparent glass substrate 1, and island-like polysilicon semiconductor layers 3 and 4 formed on the transparent glass substrate 1. The semiconductor layers 3 and 4 have central undoped channel regions 3a and 4a, a low-resistance region (source/drain region) 3c formed adjacent to the channel region 3a by heavily doping boron (B), an LDD (Lightly Doped Drain) region 4b formed adjacent to the channel region 4a by lightly doping phosphorus (P), and a low-resistance region (source/drain region) 4c formed adjacent to the LDD region 4b by heavily doping P.

A gate insulating film 6 is formed on the entire surface so as to cover the semiconductor layers 3 and 4. On the gate insulating film 6, a gate electrode 7 is formed in a region corresponding to the channel region 3a, and a gate electrode 8 is formed in a region corresponding to the channel region 4a. A capacitor upper electrode 9 for forming an auxiliary capacitor is also formed.

An interlayer dielectric film 10 is formed on the entire surface, and source electrodes 11 and 13 and drain electrodes 12 and 14 are formed. The source electrodes 11 and 13 and drain electrodes 12 and 14 are respectively connected to the low-resistance regions 3c and 4c through contact holes formed in the interlayer dielectric film 10 and gate insulating film 6.

In FIG. 1, reference numeral 21 denotes a p-channel thin-film transistor portion in, e.g., a scanning line driver; 22, an n-channel thin-film transistor portion of the display surface; and 23, an auxiliary capacitor portion.

Color filters 15 of three colors, i.e., green, blue, and red are formed, and a transparent electrode 16 is formed on the color filters 15. The transistor electrode 16 is connected to the source electrode 13 through a contact hole formed in the color filter 15.

FIG. 2 is a schematic view showing the semiconductor layer 4, the gate electrode 8, and the insulating film 6 formed between them in the n-channel thin-film transistor portion 22.

As shown in FIG. 2, the semiconductor layer 4 has the central undoped channel region 4a, the LDD region 4b formed adjacent to the channel region 4a by lightly doping phosphorus (P) and having a width w1 of, e.g., 0.8 μm, and the low-resistance region 4c formed adjacent to the LDD region 4b by heavily doping P. The insulating film 6 formed on the semiconductor layer 4 has steps, i.e., has a thickness t1 of 0.14 μm on the channel region 4a, a thickness t2 of 0.12 μm on the LDD region 4b, and a thickness t3 of 0.05 μm on the low-resistance region 4c.

In the thin-film transistor substrate of the present invention, the film thickness of the gate insulating film in the LDD portion is made different from that in the low-resistance region outside the LDD portion by controlling etching. This makes it possible to change the amount of impurity ions to be implanted into the semiconductor layer, and control the carrier concentration in each individual region. Since this obviates the need for ion implantation in the process of forming the gate electrode, it is possible to readily taper the gate electrode and improve the controllability of the LDD length, thereby obtaining high yield and high device reliability.

The step between the LDD region 4b and low-resistance region 4c is preferably 30 to 100 nm. If this step is less than 30 nm, the ion concentration difference between the LDD region 4b and low-resistance region 4c becomes difficult to control. If the step exceeds 100 nm, the film thickness of the gate insulating film increases to make good device characteristics difficult to obtain.

The width of reprocessing, which thins the gate electrode by etching, is preferably 0.1 to 1.0 μm when the processing accuracy, processing time, and the like are taken into consideration.

A spacer 17 for controlling the cell gap is also formed.

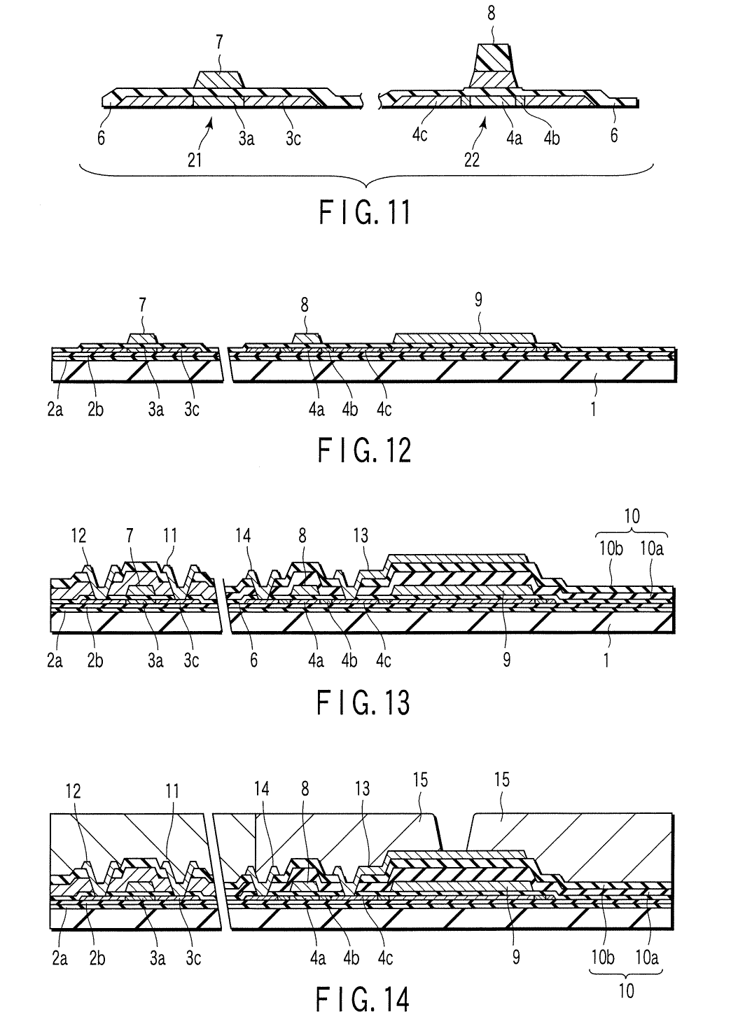

FIGS. 3 to 14 are views for explaining the first example of a method of fabricating this thin-film transistor substrate.

First, as shown in FIG. 3, SiNₓ and SiO₂ as undercoating films 2a and 2b and an amorphous silicon (a-Si) layer 18 are successively formed at 400° C. by plasma CVD on one major surface of a glass substrate 1 having outer dimensions of 550×650 mm and a thickness of 0.7 mm. The thicknesses of the SiNₓ, SiO₂, and a-Si film are respectively 0.02, 0.1, and 0.05 μm.

Then, if a large amount of hydrogen is mixed in the a-Si film, e.g., if the hydrogen concentration exceeds about 1 at %, annealing is performed at 500° C. to remove this hydrogen. This dehydrogenation makes it possible to prevent abrasion by hydrogen when polycrystallization is performed by excimer laser annealing (ELA) as the subsequent crystallization step. An a-Si film having a small hydrogen content can be obtained without any annealing depending on the film formation conditions of CVD. It is also possible to omit the annealing step if the hydrogen concentration is about 1 at % or less.

This a-Si film is polycrystallized by irradiation with XeCl excimer laser having a wavelength of 308 nm, thereby forming a polysilicon film. In this case, the a-Si film having a large area can be polycrystallized by shaping the XeCl excimer laser into a linear beam by an optical system and scanning this linear beam.

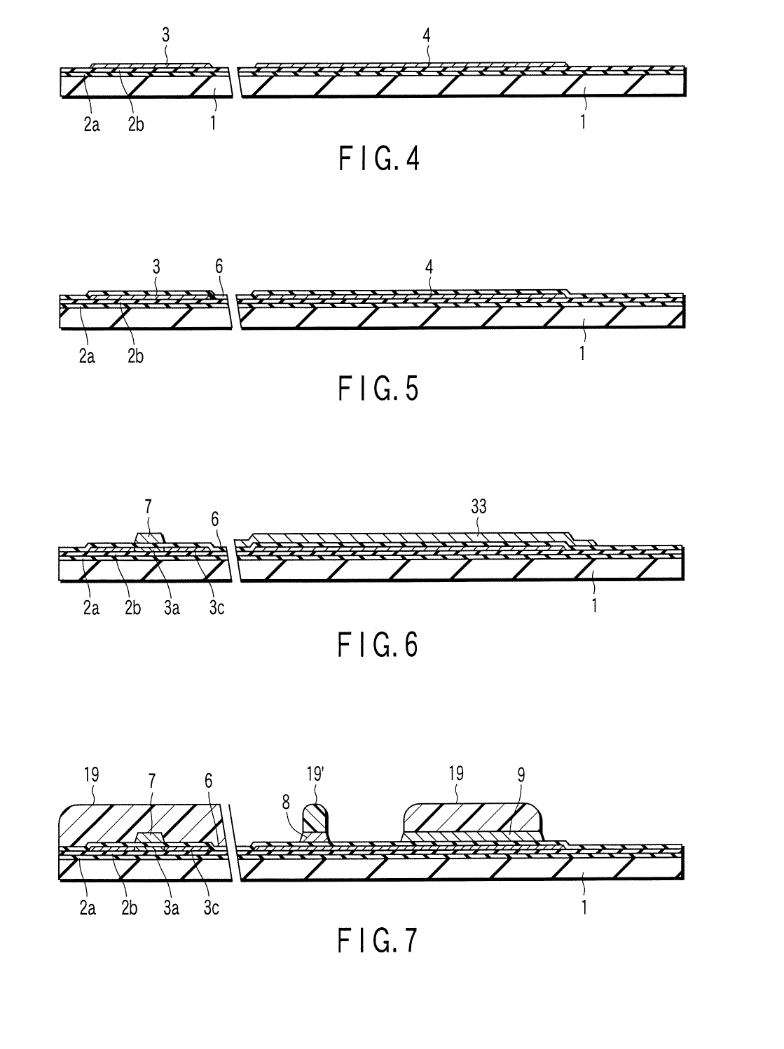

Next, as shown in FIG. 4, this polysilicon film is etched into the form of islands by photolithography to form semiconductor layers 3 and 4. In this case, taper etching of the polysilicon film can be performed by withdrawing the resist by oxygen radicals.

To adjust the conductivity of the polysilicon film to be almost intrinsic, B is lightly doped into the entire surface. The dose and acceleration voltage are appropriately 5×10¹¹/cm² and about 10 kV, respectively. This ion implantation method uses an acceleration electrode to accelerate ions generated by the formation of a plasma, thereby doping the impurity. It is desirable to implant only desired ions by separating the mass by using a magnet.

It is also possible to use a method which simultaneously implants an impurity such as hydrogen without any mass separation.

As shown in FIG. 5, a 0.14-μm thick silicon oxide SiO₂ film is formed as a gate insulating film 6 by chemical vapor deposition, e.g., plasma CVD so as to cover the semiconductor layers 3 and 4. A gas containing at least Si and O can be used as the film formation gas. An example is a gas mixture of tetraethoxysilane and O₂. As the film formation gas, it is also possible to use a combination of SiH₄ and N₂O or Si₂H₆ and N₂O, or a combination of SiH₄ and O₂ if the pressure is low.

As shown in FIG. 6, a 0.3-μm thick MoW alloy film is formed as a conductive film 33 by sputtering and etched by photolithography in, e.g., a vacuum apparatus, thereby forming a gate electrode 7. In this step, a prospective n-channel thin-film transistor region and prospective capacitor region can be protected as they are covered with a photoresist. Although this etching process uses a fluorine-based gas such as SF₆ or CF₄, taper etching can be performed by removing the resist by oxygen radicals. Subsequently, the photoresist on the electrode is removed by ashing using oxygen plasma. After that, a low-resistance region 3c is formed by heavily doping B.

A gate electrode 8 and capacitor upper electrode 9 are then formed by photolithography and etching in, e.g., a vacuum apparatus. In this step, as shown in FIG. 7, the gate electrode 7 and a prospective p-channel thin-film transistor region around it can be protected as they are covered with a photoresist 19.

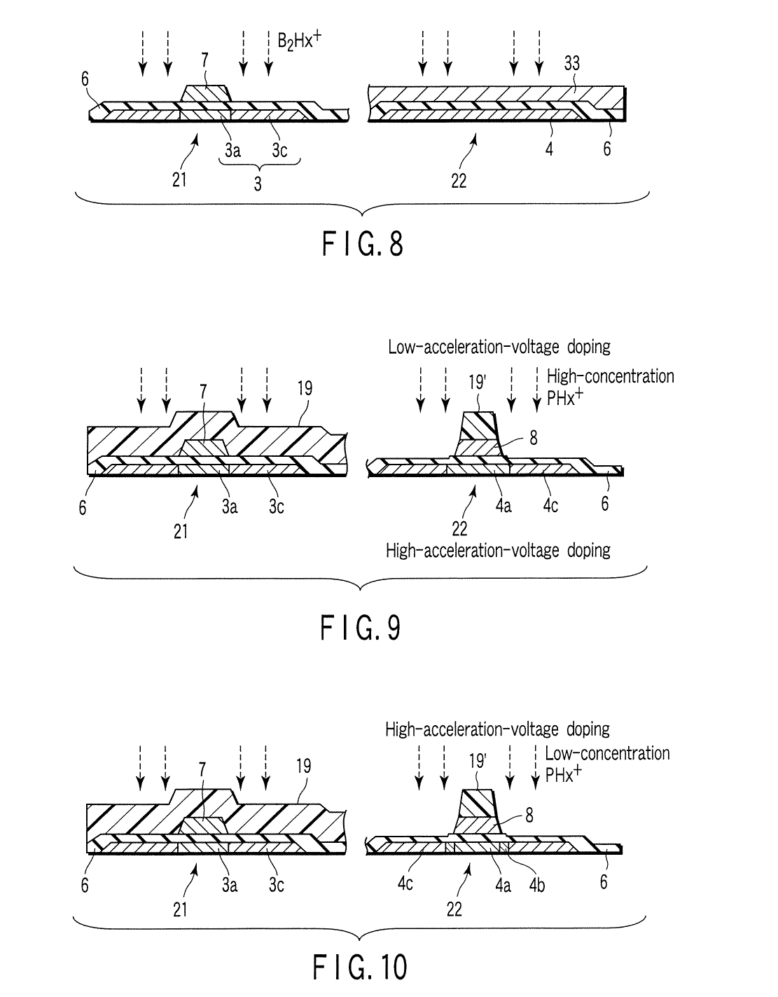

FIGS. 8 to 11 are views for explaining the formation of the p-channel thin-film transistor portion 21 and the n-channel thin-film transistor portion 22 of the display surface in more detail.

Referring to FIGS. 8 to 11, portions except for the semiconductor layers 3 and 4, gate insulating film 6, and gate electrode 7 are omitted.

As shown in FIG. 8, a low-resistance region 3c is formed by heavily doping B by using the electrode 7 as a mask. Ion doping can be used as this doping. The ion species is adjusted to mainly contain two B atoms or a monovalent ion in which H bonds to two B atoms. Examples of the ion species are B₂⁺, B₂H⁺, B₂H₂⁺, B₂H₃⁺, B₂H₄⁺, B₂H₅⁺, and B₂H₆⁺. The dose of B and the acceleration voltage can be, e.g., 1×10¹⁵/cm² and about 70 kV, respectively.

Although doping is performed after the photoresist is removed in this example, the photoresist may also remain on the MoW film when the performance of the thin-film transistor is taken into account. The photoresist remaining on the MoW film can prevent doping of B or H or ion damage that may occur through the MoW film. If ion doping is performed with the photoresist remaining, however, it is desirable to suppress the implantation ion current to stop the temperature rise of the photoresist to about 120° C., so that the photoresist hardened by ion doping poses no problem. In this case, an ashing step must be added after ion doping. To prevent ion damage without any photoresist, the film thickness of the gate electrode 7 is important. When an MoW alloy is used, the film thickness is desirably 0.2 μm or more. This similarly applies to Mo, W, and Ta. When the main component of the electrode is Al, it is desirable to leave the photoresist behind because the ion implantation blocking capability is low.

Then, a photoresist 19′ having a pattern of the gate electrode 8 of the n-channel thin-film transistor is formed by photolithography in, e.g., a vacuum apparatus. In this step, as shown in FIGS. 7 and 9, a region where the p-channel thin-film transistor 21 is to be formed is protected as it is covered with the photoresist 19.

The photoresist pattern 19′ is used as a mask to etch the gate electrode 8 of the n-channel thin-film transistor 22 by reactive ion etching (RIE) or the like by using a fluorine-based gas such as SF₆ or CF₄. Without breaking vacuum, in a plasma ambient mainly containing oxygen gas, the pattern of the photoresist 19′ on the gate electrode 8 of the n-channel thin-film transistor 22 is thinned by light ashing in, e.g., a vacuum apparatus. This light ashing is done by, e.g., exposing the substrate to a plasma ambient of a gas mainly containing oxygen gas.

Without breaking vacuum, the thinned photoresist pattern 19′ is used as a mask to etch the gate electrode 8 of the n-channel thin-film transistor 22 again in, e.g., a vacuum apparatus by using a fluorine-based gas such as SF₆ or CF₄. This reprocessing thins the gate electrode 8 of the n-channel thin-film transistor 22.

In the second etching, the etching conditions of the gate electrode 8 are set such that the gate oxide film 6 is also etched away. More specifically, when the gate electrode 8 is made of an MoW alloy, the silicon oxide film 6 can be etched away at a rate about ⅙ that of the MoW alloy by controlling the ion energy by bias power if the etching gas is a fluorine-based gas such as SF₆ or CF₄.

In the low-resistance region 4c, the first etching has exposed the silicon oxide film. Therefore, the silicon oxide film 6 is etched away by a thickness of 0.05 μm while the MoW alloy is etched by a thickness of 0.3 μm by the second etching. Assuming that the etching amount of overetching is 0.02 μm, an initial film thickness of 0.14 μm of the silicon oxide film 6 becomes 0.14−0.02=0.12 μm on the LDD region 4b, and 0.14−0.02−0.05−0.02=0.05 μm on the low-resistance region 4c.

The difference from the thickness of that portion of the insulating film which is exposed in the first etching step is preferably 30 (inclusive) to 100 (inclusive) nm, and the energy difference between the first and second ion implantation steps is preferably 25 (inclusive) to 55 (inclusive) keV.

Note that in the initial stages of this etching, it is desirable not to taper the gate electrode of the n-channel thin-film transistor but to make it almost vertical in order to decrease the pattern conversion difference. In the second etching, taper etching can be performed by removing the resist by oxygen radicals or the like. For this purpose, O₂ gas can be mixed in the etching gas.

For example, the first and second etching steps for the conductive film can be performed by exposing the substrate to a plasma ambient of an etching gas containing at least one of fluorine gas and chlorine gas. The partial pressure of oxygen gas contained in this etching gas can be higher in the second etching step than in the first etching step.

With the resist 19 remaining, P is heavily doped to form a low-resistance region 4c. Ion doping is used as this doping. The ion species is adjusted to mainly contain one P atom or a monovalent ion in which H bonds to one P atom. Examples of the ion species are P⁺, PH⁺, PH₂⁺, and PH₃⁺. The dose of P and the acceleration voltage are appropriately 1×10¹⁵/cm² and about 35 kV, respectively. At this low acceleration voltage, almost no P is doped into the LDD portion 4b having a thick residual silicon oxide film.

Subsequently, P is lightly doped to form an LDD region 4b. Ion doping is used as this doping. The ion species is adjusted to mainly contain one P atom or a monovalent ion in which H bonds to one P atom. Examples of the ion species are P⁺, PH⁺, PH₂⁺, and PH₃⁺. The dose of P and the acceleration voltage are appropriately 2×10¹³/cm² and about 80 kV, respectively. Since this time the acceleration voltage is high, P is doped into the LDD portion 4b having a thick residual silicon oxide film as well, thereby forming an LDD. Although P is also doped into the low-resistance region 4c having a thin residual silicon oxide film, it is unnecessary to take account of any adverse effect, such as destruction of the crystal of the semiconductor polysilicon film, because the dose is small.

Finally, as shown in FIG. 12, full ashing is performed using oxygen plasma to completely remove the photoresist on the gate electrode.

The width of the LDD region (the LDD length) is determined by the decrease in width of the gate electrode, and controllable by setting the conditions of light ashing and etching. The LDD length is appropriately 0.2 to 1.0 μm. When forming an LDD by patterning using a photomask, the LDD length increases to about 1.5 to 2 μm if misalignment is taken into consideration, and significantly varies. However, this method can readily form an LDD region having a length of 1.0 μm or less with no variations.

Note that in this example, P is doped with the photoresist remaining. However, it is also possible to perform full ashing subsequently to the second etching, thereby completely removing the photoresist. In this case, P is doped into the prospective p-channel thin-film transistor region as well in the second doping. Since, however, heavy doping of P is performed at a low acceleration voltage, this doping has no influence on the low-resistance region 3c where the residual silicon oxide film is thick. Although light doping of P is performed at a high acceleration voltage, this doping has no large influence on the low-resistance region 3c because the dose is small.

Also, the steps of heavy doping and light doping of P can be switched with no problem.

In the first example of the thin-film transistor substrate fabrication method according to the present invention as described above, light ashing is performed subsequently to etching to thin the photoresist pattern on the electrode, and successively the electrode is etched again by using the thinned photoresist pattern as a mask. At the same time, the series of processes of etching→light ashing→etching make the film thickness of the gate insulating film (silicon oxide) 6 on the low-resistance region 4c different from that on the LDD region 4b; the gate insulating film 6 on the low-resistance region 4c is thinner than that on the LDD region 4b.

With the resist remaining, the low-resistance region 4c is formed by heavily doping P at a low acceleration voltage, and then the LDD region 4b is formed by lightly doping P at a high acceleration voltage. Accordingly, the first example of the thin-film transistor substrate according to the first invention can control the amounts of ion implantation to the LDD region 4b and low-resistance region 4c by using the film thickness difference of the gate insulating film 6.

Subsequently, annealing is performed in a nitrogen ambient at 500° C. for 10 min to 1 hr in order to activate the doped ions. It is also possible to activate the doped ions by direct heating using a hot plate, ELA, or photoannealing using an infrared lamp. Since these methods can raise the substrate temperature within short time periods, low-cost glass can be used.

Next, the substrate is exposed to hydrogen plasma in order to terminate dangling bonds in the semiconductor layers 3 and 4, thereby performing so-called hydrogenation. If this hydrogenation is performed in a plasma CVD apparatus which forms an interlayer dielectric film 10 in the next step, the interlayer dielectric film 10 can be successively formed without exposing the substrate to the atmosphere after hydrogenation. The interlayer dielectric film 10 is then formed on the entire surface of the substrate subsequently to hydrogenation in the plasma CVD apparatus described above. In this example, a 0.42-μm thick silicon nitride layer 10a is formed first, and then a 0.35-μm thick silicon oxide layer 10b is formed. These film thicknesses are set to obtain the highest optical transmittance when the refractive index of silicon nitride is 1.88 and that of silicon oxide is 1.47. The silicon nitride layer 10a protects the gate insulating film 6 of the thin-film transistor from external impurity contamination, and also blocks removal of hydrogen doped into the semiconductor layers 3 and 4 by hydrogenation. Therefore, the film thickness of the silicon nitride layer is desirably larger than that of the electrodes 7, 8, and 9, and must be 0.3 μm or more in this example. Under these conditions, a film thickness with which a high transmittance is obtained is 0.42 μm. The film thickness of silicon oxide may also be 0.17 μm.

Subsequently, the gate insulating film 6 and interlayer dielectric film 10 on portions of the low-resistance regions 3c and 4c are etched away by photolithography to form control holes.

Stacked films of Mo (0.05 μm)/Al (0.5 μm)/Mo (0.05 μm) are then formed by sputtering. Mo as the lowermost electrode layer is connected to the low-resistance regions 3c and 4c through the contact holes. Ti can also be used as the electrode material instead of Mo. As shown in FIG. 13, source electrodes 11 and 13 and drain electrodes 12 and 14 are formed by patterning using photolithography.

After that, photosensitive color filters 15 of three colors, i.e., green, blue, and red are formed on desired pixels by photolithography, and a contact hole is formed in an auxiliary capacitance region.

Then, ITO is formed as a transparent electrode 16, and connected to the source electrode 13 through the contact hole formed in the color filter 15. Finally, a spacer 17 for controlling the cell gap is formed by patterning, thereby obtaining a desired thin-film transistor array as shown in FIG. 1.

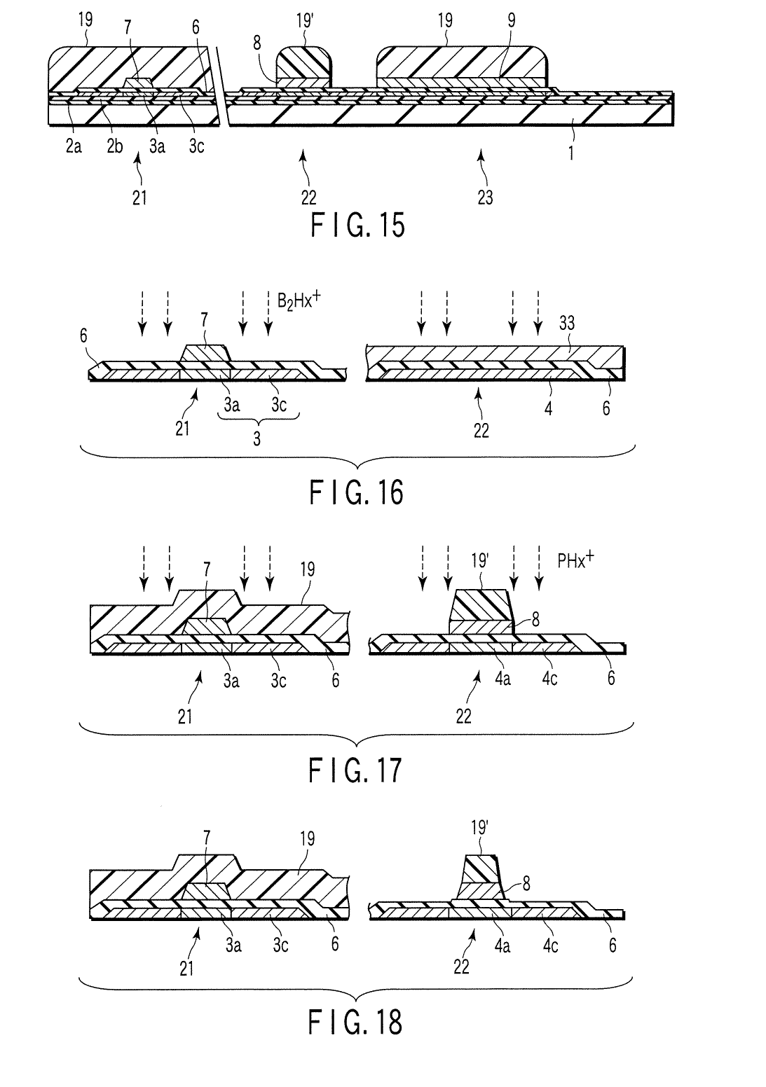

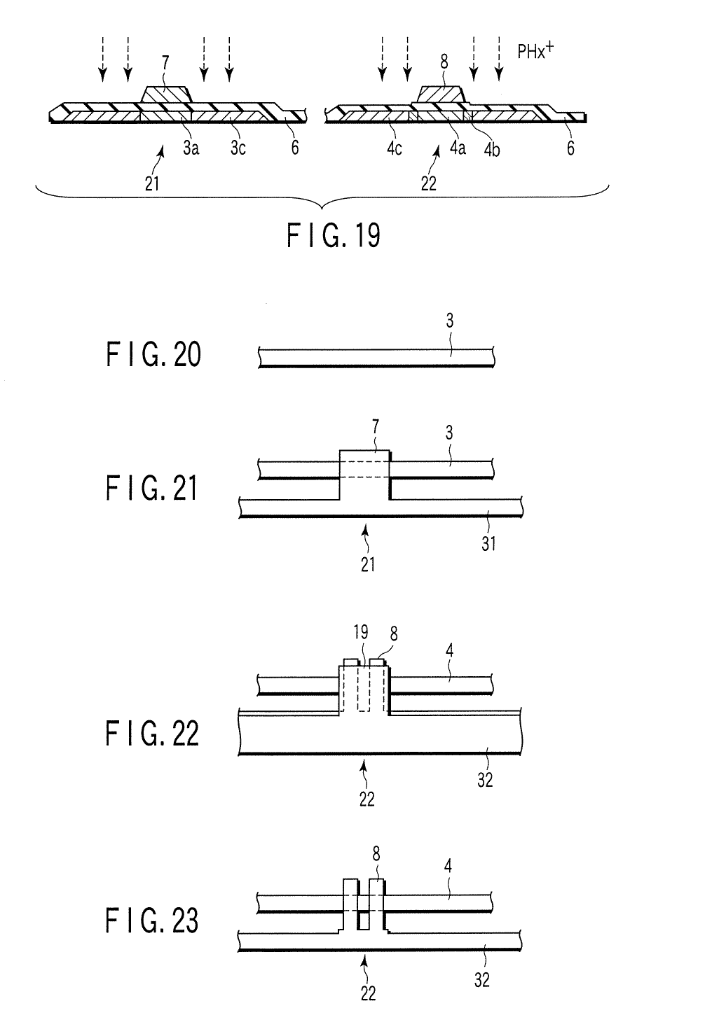

The second example of the thin-film transistor fabrication method according to the present invention will be explained below with reference to FIGS. 15 to 19.

As in the steps shown in FIGS. 2 to 6 described above, island-like polysilicon semiconductor layers 3 and 4 and a gate insulating film 6 are formed on a transparent glass substrate 1.

FIGS. 16 to 19 are views for explaining the formation of a p-channel thin-film transistor portion 21 and an n-channel thin-film transistor 22 of the display surface in more detail.

Referring to FIGS. 16 to 19, portions except for the semiconductor layers 3 and 4, the gate insulating film 6, and a gate electrode 7 are omitted.

As shown in FIG. 16, a 0.3-μm thick MoW alloy film is formed on the gate insulating film 6 by sputtering and etched by photolithography, thereby forming a gate electrode 7 of the p-channel thin-film transistor portion 21. In this step, a portion where the n-channel thin-film transistor portion 22 is to be formed can be protected as it is covered with a photoresist 19. Although this etching process uses a fluorine-based gas such as SF₆ or CF₄, taper etching can be performed by removing the resist by oxygen radicals. Subsequently, the photoresist on the gate electrode 7 is removed by ashing using oxygen plasma.

As in the step shown in FIG. 8, a low-resistance region 3c is formed by heavily doping B by using the gate electrode 7 as a mask. Ion doping is used as this doping. The ion species is adjusted to mainly contain two B atoms or a monovalent ion in which H bonds to two B atoms. Examples of the ion species are B₂⁺, B₂H⁺, B₂H₂⁺, B₂H₃⁺, B₂H₄⁺, B₂H₅⁺, and B₂H₆⁺. The dose of B and the acceleration voltage can be, e.g., 1×10¹⁵/cm² and about 70 kV, respectively.

Although doping is performed after the photoresist is removed in this example, the photoresist may also remain on the MoW film as explained in the above embodiment.

Then, as shown in FIGS. 15 and 17, a photoresist 19′ having patterns of a gate electrode 8 and capacitor upper electrode 9 is formed. A gate electrode 8 and capacitor upper electrode 9 of the n-channel thin-film transistor are formed by etching. In this step, a region where the p-channel thin-film transistor is to be formed is protected as it is covered with the photoresist 19. After the etching, the photoresist is left behind without performing any ashing.

In this stage, the gate electrode of the n-channel thin-film transistor need not be tapered. It is rather desirable to make this gate electrode almost vertical in order to decrease the pattern conversion difference.

With the resist remaining, P is heavily doped by using the gate electrode 8 and capacitor upper electrode 9 as masks, thereby forming a low-resistance region 4c. Ion doping is used as this doping.

The ion species is adjusted to mainly contain one P atom or a monovalent ion in which H bonds to one P atom. Examples of the ion species are P⁺, PH⁺, PH₂⁺, and PH₃⁺. The dose of P and the acceleration voltage are appropriately 1×10¹⁵/cm² and about 70 kV, respectively.

As shown in FIG. 18, the photoresist pattern 19′ on the gate electrode 8 of the n-channel thin-film transistor and on the capacitor upper electrode 9 is thinned by light ashing by using RIE or the like in a plasma ambient mainly containing oxygen gas. Successively, the thinned photoresist pattern 19′ is used as a mask to etch the gate electrode 8 of the n-channel thin-film transistor and the capacitor upper electrode 9 again by using a fluorine-based gas such as SF₆ or CF₄. This reprocessing thins the gate electrode 8 of the n-channel thin-film transistor and the capacitor upper electrode 9.

Note that taper etching can be performed by removing the resist by oxygen radicals. For this purpose, O₂ gas is mixed in the etching gas.

Light ashing before etching thins the photoresist pattern 19′, and also removes the surface modified layer of the photoresist hardened by ion doping (heavy doping of P) in the preceding step. If this modified layer is not removed, a taper is difficult to form in the etching step. For this reason, light ashing is desirably performed not before, but after ion doping.

When etching the gate electrode, the gate insulating film (silicon oxide) in an LDD portion is etched away by about 0.03 μm in the film thickness direction by extending etching. In this manner, an initial film thickness of 0.12 μm of the silicon oxide, which corresponds to t1 in FIG. 2, becomes a residual film thickness of 0.09 μm, which is smaller than 0.1 μm, in the LDD portion, which corresponds to t2 in FIG. 2. This makes it possible to efficiently perform ion doping of an LDD portion 4b in the next step with small variations in ion implantation amount. At the same time, the silicon oxide film in the low-resistance region 4c is further etched away to obtain a film thickness of 0.05 μm in a portion corresponding to t3 in FIG. 2. When ion doping of the LDD portion 4b is performed, ions are efficiently implanted into the low-resistance region 4c, so an interconnection with a low resistance can be formed.

The photoresist on the gate electrode is completely removed by performing full ashing using oxygen plasma subsequently to etching.

The LDD region 4b is formed by lightly doping P by using the electrodes 7, 8, and 9 as masks. Ion doping is used as this doping. The ion species is adjusted to mainly contain one P atom or a monovalent ion in which H bonds to one P atom. Examples of the ion species are P⁺, PH⁺, PH₂⁺, and PH₃⁺. The dose of P and the acceleration voltage are appropriately 2×10¹³/cm² and about 80 kV, respectively.

When the residual silicon oxide film thickness in the LDD portion is 0.09 μm, about 40% of the whole dose of P is implanted into the polysilicon film.

The width of the LDD region (the LDD length) is determined by the decrease in width of the gate electrode, and controllable by setting the conditions of light ashing and etching. The LDD length is appropriately 0.2 to 1.0 μm. When forming an LDD by patterning using a photomask, the LDD length increases to about 1.5 to 2 μm if misalignment is taken into consideration, and significantly varies. As in the above embodiment, however, this method can readily form an LDD region having a length of 1.0 μm or less.

In the second example of the thin-film transistor substrate fabrication method of the present invention, the gate electrode 8 and capacitor upper electrode 9 are formed by photolithography and etching. While the photoresist is left behind by performing no ashing after etching, P is heavily doped by using the gate electrode 8 and capacitor upper electrode 9 as masks, thereby forming the low-resistance region 4c. In addition, RIE or the like is used to expose the substrate to a plasma ambient of an etching gas mainly containing oxygen gas, thereby thinning the photoresist pattern on the electrodes 8 and 9. The thinned photoresist pattern is used as a mask to etch the gate electrode 8 and capacitor upper electrode 9 again by using a fluorine-based gas such as SF₆ or CF₄ while removing the resist by oxygen radicals. This etching process is also performed such that taper etching can be performed. This reprocessing thins the gate electrode 8 and capacitor upper electrode 9.

The LDD region 4b is formed by lightly doping P by using the electrodes 7, 8, and 9 as masks. The second example of the thin-film transistor substrate according to the present invention can control the amounts of ion implantation to the LDD region 4b and low-resistance region 4c by using the film thickness difference of the gate insulating film 6.

In this example, doping is performed after the photoresist is removed as in the first example of the thin-film transistor substrate fabrication method. However, the photoresist may also remain on the MoW film when the performance of the thin-film transistor is taken into account. To prevent ion damage without any photoresist, the film thickness of the gate electrode is important. When an MoW alloy is used, a film thickness of 0.2 μm or more is necessary. This almost similarly applies to Mo, W, and Ta. When the main component of the electrode is Al, it is desirable to leave the photoresist behind because the ion implantation blocking capability is low.

Subsequently, annealing is performed in a nitrogen ambient at 500° C. for 10 min to 1 hr in order to activate the doped ions. It is also possible to activate the doped ions by direct heating using a hot plate, ELA, or photoannealing using an infrared lamp. Since these methods can raise the substrate temperature within short time periods, low-cost glass can be used.

Next, the substrate is exposed to hydrogen plasma in order to terminate dangling bonds in the semiconductor layers 3 and 4, thereby performing so-called hydrogenation. If this hydrogenation is performed in a plasma CVD apparatus which forms an interlayer dielectric film 10 in the next step, the interlayer dielectric film 10 can be successively formed without exposing the substrate to the atmosphere. The interlayer dielectric film 10 is then formed on the entire surface of the substrate subsequently to hydrogenation in the plasma CVD apparatus described above. In this example, a 0.42-μm thick silicon nitride film is formed first, and then a 0.35-μm thick silicon oxide film is formed. These film thicknesses are set to obtain the highest optical transmittance when the refractive index of silicon nitride is 1.88 and that of silicon oxide is 1.47. The silicon nitride film protects the gate insulating film 6 of the thin-film transistor from external impurity contamination, and also blocks removal of hydrogen doped into the semiconductor layers 3 and 4 by hydrogenation. Therefore, the film thickness of the silicon nitride film is desirably larger than that of the electrodes 7, 8, and 9, and must be 0.3 μm or more in this example. Under the conditions, a film thickness with which a high transmittance is obtained is 0.42 μm. The film thickness of the silicon oxide film may also be 0.17 μm.

Subsequently, the gate insulating film 6 and interlayer dielectric film 10 on portions of the low-resistance regions 3c and 4c are etched away by photolithography to form control holes.

Stacked films of Mo (0.05 μm)/Al (0.5 μm)/Mo (0.05 μm) are then formed by sputtering. Mo as the lowermost electrode layer is connected to the low-resistance regions 3c and 4c through the contact holes. Ti can also be used as the electrode material instead of Mo. Source electrodes 11 and 13 and drain electrodes 12 and 14 are formed by patterning using photolithography.

After that, photosensitive color filters 15 of three colors, i.e., green, blue, and red are formed on desired pixels by photolithography, and a contact hole is formed in an auxiliary capacitance region.

Then, ITO is formed as a transparent electrode 16, and connected to the source electrode 13 through the contact hole formed in the color filter 15. Finally, a spacer 17 for controlling the cell gap is formed by patterning, thereby obtaining a desired thin-film transistor array.

As an application example of the thin-film transistor substrate described above, the gate interconnection may also be integrated with the gate electrode of the p-channel thin-film transistor.

FIGS. 20 to 23 are views for explaining an example of the fabrication of a gate electrode and gate interconnection preferably used in the present invention.

First, as shown in FIG. 20, a semiconductor layer 3 serving as the channel, source, and drain of a thin-film transistor and a semiconductor layer 4 (not shown) are formed.

A gate insulating film is formed on the entire surface so as to cover the semiconductor layers 3 and 4. After that, a metal film is formed on the gate insulating film by sputtering, and a gate electrode pattern 7 of a p-channel thin-film transistor is formed by photolithography as shown in FIG. 21. In this stage, a gate interconnection 31 and a gate interconnection 32 (not shown) are formed even in a pixel display region where no p-channel thin-film transistor is to be formed. No pattern is formed in a prospective n-channel thin-film transistor portion.

Then, a gate electrode is formed in the prospective n-channel thin-film transistor portion. As described previously, in the gate electrode of the prospective n-channel thin-film transistor portion, an LDD can be formed in self-alignment by performing etching twice. Referring to FIG. 22, a gate electrode 8 of the n-channel thin-film transistor has a double-gate structure in which two thin-film transistors are connected in series.

The gate interconnection 32 already formed by pattering upon photolithography of the p-channel thin-film transistor is protected during photolithography of the p-channel thin-film transistor by leaving a photoresist 19 behind in a wide area.

Finally, the gate interconnection 32 and the gate electrode 8 of the n-channel double-gate thin-film transistor are finished as shown in FIG. 23.

In this method, portions where the conductive film made of MoW or the like is etched twice can be limited to portions where an LDD region must be formed as an n-channel thin-film transistor, e.g., a switching thin-film transistor portion of a pixel and an n-channel thin-film transistor portion of a CMOS circuit.

When the MoW film of the n-channel thin-film transistor is processed, a wide area of the gate interconnection formed when the p-channel thin-film transistor is processed is covered with a photoresist. The width of the gate interconnection is normally 3 to 7 μm, and typically about 5 μm. If the gate interconnection is covered with a photoresist having a width of 10 μm or more when the MoW film of the n-channel thin-film transistor is processed, the photoresist hardly disappears during the processing, and this prevents disconnection of the gate interconnection.

The gate interconnecting portion is formed by patterning when the p-channel thin-film transistor is processed, and has a shape in which the gate electrode of the n-channel thin-film transistor protrudes from the gate interconnection. Therefore, even if the gate electrode of the n-channel thin-film transistor disappears during the etching process, this does not lead to a fatal defect, i.e., disconnection of the gate interconnection.

Furthermore, the n-channel thin-film transistor also has a double-gate structure as shown in the drawing. Accordingly, even if one gate electrode disappears during the etching process, at least a single-gate thin-film transistor is fabricated. Since the device is still controllable, the occurrence of defective display can be prevented.

The use of the mask pattern as described above can prevent the decrease in yield caused by disappearance of the gate interconnection and gate electrode, which is a serious problem when the LDD of an n-channel thin-film transistor is formed in self-alignment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A thin-film transistor fabrication method comprising:
a step of forming an island-like semiconductor layer on an insulating substrate;
a step of forming an insulating film to cover the semiconductor layer;
a step of forming a conductive film to cover the insulating film;
a first etching step of forming a pattern of a photoresist on the conductive film, and processing the conductive film by using the photoresist as a mask;
a step of thinning the pattern of the photoresist by reprocessing;
a second etching step of thinning the conductive film by reprocessing by using the reprocessed pattern of the photoresist as a mask, and forming a step on the insulating film by etching away, in a film thickness direction, a portion of the insulating film which is exposed in the first etching step for the conductive film;
an ion implantation step of implanting impurity ions into the semiconductor layer by using the photoresist and conductive film having undergone the second etching step as masks; and
a step of removing the photoresist.

2. A method according to claim 1, wherein the insulating film is made of a silicon oxide film.

3. A method according to claim 1, wherein the first etching step, the step of reprocessing, and the second etching step are successively performed in the same reaction chamber of a vacuum apparatus.

4. A method according to claim 1, wherein the step of removing the photoresist is performed before the ion implantation step.

5. A method according to claim 4, wherein the first etching step, the step of reprocessing, the second etching step, and the step of removing the photoresist are successively performed in the same reaction chamber of a vacuum apparatus.

6. A method according to claim 1, wherein the ion implantation step comprises a first ion implantation step which uses a low energy and a high dose, and a second ion implantation step which uses a high energy and a low dose.

7. A method according to claim 6, wherein the semiconductor layer is a polycrystalline semiconductor layer, an amount of phosphorus ions implanted into the polycrystalline semiconductor layer below the portion of the insulating film which is exposed in the first etching step is 5×10¹³ (inclusive) to 1×10¹⁵ (inclusive) cm⁻², and an amount of phosphorus ions implanted into the polycrystalline semiconductor layer below a portion of the insulating film which is exposed in the second etching step is 4×10¹² (inclusive) to 2×10¹³ (inclusive) cm⁻².

8. A method according to claim 6, wherein the semiconductor layer is a polycrystalline semiconductor layer, a sheet resistance of the polycrystalline semiconductor layer below the portion of the insulating film which is exposed in the first etching step is 0.5 (inclusive) to 8 (inclusive) kΩ/cm², and a sheet resistance of the polycrystalline semiconductor layer below a portion of the insulating film which is exposed in the second etching step is 10 (inclusive) to 100 (inclusive) kΩ/cm².

9. A method according to claim 1, wherein the semiconductor layer is a polycrystalline semiconductor layer, and a difference between a thickness of the portion of the insulating film which is exposed in the first etching step and a thickness of a portion of the insulating film which is exposed in the second etching step is 30 (inclusive) to 100 (inclusive) nm.

10. A method according to claim 6, wherein an energy difference between the first ion implantation step and the second ion implantation step is 25 (inclusive) to 55 (inclusive) keV.

11. A thin-film transistor fabrication method comprising:
a step of forming an island-like semiconductor layer on an insulating substrate;
a step of forming a gate insulating film to cover the semiconductor layer;
a step of forming a conductive film to cover the gate insulating film;
a first etching step of forming a pattern of a photoresist on the conductive film, and processing the conductive film by using the photoresist as a mask;
a step of removing the photoresist on the conductive film;
a first ion implantation step of implanting impurity ions into the semiconductor layer by using the processed conductive film as a mask;
a second etching step of forming a pattern of a photoresist on the conductive film, and processing the conductive film by using photoresist as a mask;
a step of thinning the pattern of the photoresist by reprocessing;
a third etching step of thinning the conductive film by reprocessing by using the reprocessed pattern of the photoresist as a mask, and forming a step on the gate insulating film by deeply etching away a portion of the insulating film which is exposed in the second etching step for the conductive film;
a second ion implantation step of implanting impurity ions into the semiconductor layer by using the photoresist and conductive film having undergone the third etching step as masks; and
a step of removing the photoresist on the conductive film.

12. A method according to claim 11, wherein the step of removing the photoresist is performed before the second ion implantation step.

13. A method according to claim 11, wherein the step of reprocessing is light ashing and performed by exposing the substrate to a plasma ambient of a gas mainly containing oxygen gas.

14. A method according to claim 11, wherein the first etching step and second etching step of processing the conductive film are performed by exposing the substrate to a plasma ambient of an etching gas containing at least one of fluorine gas and chlorine gas, and a partial pressure of oxygen gas contained in the etching gas is higher in the second etching step than in the first etching step.

15. A thin-film transistor fabrication method comprising:
a step of forming an island-like semiconductor layer on an insulating substrate;
a step of forming an insulating film to cover the semiconductor layer;
a step of forming a conductive film to cover the insulating film;
a first etching step of forming a pattern of a photoresist on the conductive film, and processing the conductive film by using the photoresist as a mask;
a first ion implantation step of implanting impurity ions into the semiconductor layer by using the pattern of the photoresist and the conductive film as masks;
a step of thinning the pattern of the photoresist by reprocessing using etching;
a second etching step of thinning the conductive film by reprocessing by using the reprocessed pattern of the photoresist as a mask;
a step of removing the photoresist on the conductive film; and
a second ion implantation step of implanting the impurity ions into the semiconductor layer by using the reprocessed conductive film as a mask.

16. A method according to claim 15, wherein in the second etching step, the conductive film is thinned by reprocessing by using the reprocessed pattern of the photoresist as a mask, and a step is formed on the insulating film by etching away, in a film thickness direction, a portion of the insulating film which is exposed in the first etching step for the conductive film.

17. A method according to claim 15, wherein
the semiconductor layer is a polycrystalline semiconductor layer mainly containing silicon, and
the insulating film is a gate insulating film mainly containing a silicon oxide film.

18. A method according to claim 15, wherein a width of reprocessing of the conductive film is 0.1 (inclusive) to 1.0 (inclusive) μm.

19. A thin-film transistor fabrication method comprising:
a step of forming an island-like semiconductor layer on an insulating substrate;
a step of forming an insulating film to cover the semiconductor layer;
a step of forming a conductive film to cover the insulating film;
a first etching step of forming a pattern of a photoresist on the conductive film, and processing the conductive film by using the photoresist as a mask;
a first ion implantation step of implanting impurity ions into the semiconductor layer by using the pattern of the photoresist and the conductive film as masks;
a step of thinning the pattern of the photoresist by reprocessing using etching;
a second etching step of thinning the conductive film by reprocessing by using the reprocessed pattern of the photoresist as a mask, and forming a step on the insulating film by etching away, in a film thickness direction, a portion of the insulating film which is exposed in the first etching step for the conductive film;
a second ion implantation step of implanting impurity ions into the semiconductor layer by using the reprocessed conductive film and the photoresist on the conductive film as masks; and
a step of removing the photoresist on the conductive film after the second ion implantation step.

20. A method according to claim 19, wherein
the semiconductor layer is a polycrystalline semiconductor layer mainly containing silicon, and
the insulating film is a gate insulating film mainly containing a silicon oxide film.

21. A method according to claim 19, wherein a width of reprocessing of the conductive film is 0.1 (inclusive) to 1.0 (inclusive) μm.

22. A thin-film transistor comprising:
an insulating substrate;
a semiconductor layer formed to be isolated in a form of an island on the insulating substrate to form a channel and mainly containing silicon;
a gate insulating film formed to cover the semiconductor layer and mainly containing a silicon oxide film; and
a gate electrode and source/drain electrodes formed on the gate insulating film,
the semiconductor layer having an LDD region formed by implanting low-concentration impurity ions into a region outside the gate electrode, and low-resistance source/drain regions being formed by implanting high-concentration impurity ions outside the LDD region,
wherein a film thickness of the gate insulating film on the LDD region is smaller than a film thickness of the gate insulating film in a channel region below the gate electrode, and a film thickness of the gate insulating film below the source/drain electrodes is smaller than the film thickness of the gate insulating film on the LDD region.

23. A transistor according to claim 22, wherein a width of the LDD region is 0.1 (inclusive) to 1.0 (inclusive) μm.

24. A transistor according to claim 22, wherein the semiconductor layer is made of polysilicon, a sheet resistance of the semiconductor layer in the source/drain regions is 0.5 (inclusive) to 8 (inclusive) kΩ/cm², and a sheet resistance of the semiconductor layer in the LDD region is 10 (inclusive) to 100 (inclusive) kΩ/cm².

25. A thin-film transistor fabrication method comprising:
a step of forming an island-like semiconductor layer mainly containing silicon on an insulating substrate;
a step of forming a gate insulating film mainly containing a silicon oxide film to cover the semiconductor layer;
a step of forming a conductive film to cover the gate insulating film;
a first etching step of forming a photoresist having a first pattern on the conductive film, and processing the conductive film by using the photoresist as a mask;
a step of removing the photoresist having the first pattern;
a first ion implantation step of implanting group-III impurity ions into the semiconductor layer by using the conductive film as a mask;
a second etching step of forming a photoresist having a second pattern on the conductive film, and processing the conductive film by using the photoresist having the second pattern as a mask;
a second ion implantation step of implanting group-V impurity ions into the semiconductor layer by using the photoresist having the second pattern and the conductive film as masks;
a step of thinning the second pattern of the photoresist by reprocessing using etching after the second ion implantation step;
a third etching step of thinning the conductive film by reprocessing by using the photoresist having the reprocessed second pattern as a mask, and forming a step on the gate insulating film by etching away, in a film thickness direction, a portion of the gate insulating film which is exposed in the second etching step for the conductive film;
a step of removing the photoresist having the reprocessed second pattern; and
a third ion implantation step of implanting group-V impurity ions into the semiconductor layer by using the reprocessed conductive film as a mask.

26. A method according to claim 25, wherein
the step of removing the photoresist having the first pattern is performed after the first ion implantation step and before the second etching step, and
the step of removing the photoresist having the second pattern is performed after the third ion implantation step.

27. A method according to claim 25, wherein the step of thinning the photoresist having the second pattern by reprocessing using etching is performed by exposing the substrate to a plasma ambient of an etching gas mainly containing oxygen gas.

28. A method according to claim 25, wherein the first etching step and second etching step of processing the conductive film are performed by exposing the substrate to a plasma ambient of an etching gas containing at least one of fluorine gas and chlorine gas, and a partial pressure of oxygen gas contained in the etching gas is higher in the second etching step than in the first etching step.
